(19) United States
(12) Patent Application Publication
(10) Pub. No.: US 2002/0031917 A1
(43) Pub. Date: Mar. 14, 2002

(54) Method for forming porous film, insulating film for semiconductor element, and method for forming such insulating film

(76) Inventors: Takashi Nire, Hiratsuka-shi (JP); Akira Matsuno, Hiratsuka-shi (JP); Kazuhiro Kagawa, Hiratsuka-shi (JP); Mika Mukoujima, Hiratsuka-shi (JP)

Correspondence Address: VARNDELL & VARNDELL, PLLC, 106-A S. COLUMBUS ST., ALEXANDRIA, VA, 22314, US

(21) Appl. No.: 09/946,635

(22) Filed: Sep. 6, 2001

(30) Foreign Application Priority Data
Sep. 11, 2000 (JP) 274956/2000
Dec. 22, 2000 (JP) 390671/2000

(51) Int. Cl. H01L 21/31

(52) U.S. Cl. 438/778

(57) ABSTRACT

When laser ablation is implemented with respect to a target comprising silicon in an atmosphere containing oxygen, Si constituting the target is ejected from the laser irradiated portion thereof. The ejected Si collides with oxygen, which is the atmosphere gas, and reacts therewith in a gas phase forming clusters composed of SiO₂ or SiOx, or silicon (Si) and oxygen, and containing pores with a size of several nanometers. The clusters adhere to the substrate, thereby forming a porous film composed of Si and oxygen and containing pores on the substrate. Furthermore, an insulating film for a semiconductor element is formed to have a multilayer structure in which an aggregate is deposited on the substrate and then a dense film is formed. When the insulating film is formed, the aggregate is produced by implementing laser ablation under a pressure of 1 Kpa, for example. Then, a pressure transition from this 1 KPa to 10 Pa, for example, is caused and a dense film is formed by implementing laser ablation under this pressure of this 10 Pa by adjusting a parameter (for example, laser energy density) other than pressure. The thickness of each layer in the multilayer structure composed of the aggregate and dense film and the thickness ratio of the layers is adjusted by adjusting the number of times the target is irradiated with the laser beam.

### BACKGROUND OF THE INVENTION

1. Field of the Invention

The present invention relates to a method for forming a porous film serving as an interlayer insulating film of semiconductors, and also to an insulating film for a semiconductor element having a low relative dielectric constant, and to a method for forming such insulating film.

2. Description of the Related Art

Conventional semiconductor memory devices, e.g., LSI have been designed and implemented, for example, according to a 0.13 μm or 0.15 μm design rule.

In the operation of such LSI, a problem is associated with a signal delay proportional to a product of wiring resistance (resistance component) and capacitance between wirings (capacitance components). For this reason, it is necessary to decrease the time constant τ∝(C·R)(C=electrostatic capacitance, R=resistance value) defined by wirings.

For example, as for wiring resistance, the transition from AlCu wiring to Cu wiring resulted in a decreased resistance. On the other hand, the electrostatic capacitance was decreased by forming an interlayer insulating film such that decreases the relative dielectric constant related to the capacitance between wirings.

A known method for forming a porous film as an interlayer insulating film of semiconductor devices was described in Japanese Patent Application Laid-open No. 11-31690.

With the method described in this open publication, a SOG solution (solution for forming a porous film) comprising an organosilicon compound having a polar group is coated on a substrate to form a coating film and then the coating film is made porous by heating. As a result, a porous film with a relative dielectric constant of 2.0 was realized.

However, in the field of semiconductor memory devices, for example, LSI a 0.07 μm design rule has recently been considered to conduct even finer processing than that based on the above-mentioned 0.13 or 0.15 μm rule. The generation of devices of this 0.07 μm design rule are said to require the decrease in the relative dielectric constant of interlayer insulating films to 1.5.

However, though the above-described openly disclosed conventional method makes it possible to form a porous film (interlayer insulating film) with a relative dielectric constant of 2.0, it fails to reach a level of relative dielectric constant of 1.5 required by the 0.07 μm design rule of the next generation.

Accordingly, a first object of the present invention is to form a porous film with a low relative dielectric constant as an interlayer insulating film of semiconductors.

Furthermore, with the above-described openly disclosed conventional method in which a porous film is formed by coating a precursor solution for the formation of the porous film on a substrate, the precursor solution has to be prepared in advance. One more problem is that the precursor solution itself undergoes chemical changes and degrades with time, making it impossible to form a stable porous film.

Furthermore, with the above-described openly disclosed conventional method, a large amount of precursor solution becomes wastewater during coating. Accordingly problems of cost increase and environmental load are also associated with this method.

Thus, a second object of the present invention is to form easily a stable porous film with a low relative dielectric constant suitable as an interlayer insulating film of semiconductors and to form a porous film at a reduced cost and in an environmentally friendly manner.

A known method for forming interlayer insulating films for semiconductor devices was described in Japanese Patent Application Laid-open No. 11-186258.

With this openly disclosed method, an interlayer insulating film with a relative dielectric constant (in the publication a term dielectric constant was apparently erroneously used instead of relative dielectric constant) having a three-layer structure composed of an airtight high-grade silicon oxide film (SiO₂), a porous silicon oxide film, and an airtight high-grade silicon oxide film (SiO₂) was formed with a CVD apparatus comprising a plasma CVD chamber and a plasma etching chamber. Furthermore, continuous film forming was made possible by changing process conditions of high-density plasma CVD and plasma etching.

As described above, in the semiconductor memory, for example, LSI of 0.07 μm design rule generation, the relative dielectric constant of interlayer insulating film has to be decreased to 1.5.

However, according to the method as described in the above-mentioned publication, it is possible to form an interlayer insulation film having a relative dielectric constant of 2.5 to 3.5, but it is impossible to achieve a relative dielectric constant of 1.5 that is required by 0.07 μm design rule of the next generation.

Thus, a third object of the present invention is to provide an insulating film for a semiconductor element having a relative dielectric constant of no more than about 0.2 and a method for forming such insulating film.

In the above-mentioned open publication, an interlayer insulating film is formed by CVD (chemical vapor deposition). Therefore, even if the supply of reaction gas is terminated, for example, to obtain the desired thickness of the insulating film, when a chemical reaction proceeds inside the chamber at this time, the film is deposited because of the chemical reaction. As a result, the control of film thickness and thickness ratio of various layers cannot be conducted with good accuracy.

Accordingly, it is a fourth object of the present invention to provide a method for forming an insulating film for a semiconductor element, which makes it possible to conduct the control of film thickness and thickness ratio of various layers with good accuracy when an insulating film with a low dielectric constant is formed as an interlayer insulating film for a semiconductor element.

Furthermore, in the above-described open publication, an interlayer insulating film with a three-layer structure was formed with a multimodule system comprising a plasma CVD chamber and a plasma etching chamber. Therefore, a plurality of chambers were necessary. Moreover, an apparatus was required for transporting the semiconductor substrates to be processed between the chambers. For this reason, the entire apparatus had a complex structure.

Accordingly, it is a fifth object of the present invention to provide a method for forming an insulating film for a semiconductor element, which makes it possible to form an insulating film with a low dielectric constant as an interlayer insulating film for a semiconductor element in one chamber.

### SUMMARY OF THE INVENTION

In order to attain the above-described first and second objects, with the method for forming a porous film in accordance with the first aspect of the present invention, a porous film composed of silicon and oxygen and containing pores is formed on a substrate by a laser ablation method using silicon as a target and conducted in a gas containing oxygen.

In accordance with the second aspect of the present invention, in the porous film of the first aspect of the present invention, the relative dielectric constant of the porous film is adjusted so that it assumes the desired value.

In order to attain the above-described first and second objects, the method for forming a porous film in accordance with the third aspect of the present invention comprises a disposition step of disposing a target composed of silicon and a substrate inside a chamber at a predetermined distance from each other, an introducing step of introducing a gas comprising oxygen inside the chamber, and a film forming step of forming a porous film consisting of silicon and oxygen and containing pores on the substrate by irradiating the target with a laser beam from outside of the chamber which has the gas composed of oxygen introduced therein.

Furthermore, in accordance with the fourth aspect of the present invention, in the method of the third aspect of the present invention, the film forming step comprises a step of adjusting the relative dielectric constant of the porous film so that it assumes the desired value.

The invention according to the first and second aspects thereof will be described below with reference to FIG. 1 and FIG. 2.

As shown in FIG. 1, a substrate 60 and a target 70 are disposed opposite each other inside a vacuum chamber 20. Vacuum chamber 20 is then evacuated with a vacuum pump 30, a gas inlet valve (not shown in the figure) is opened, and, for example, oxygen is introduced into vacuum chamber 20 within a pressure range from several Torr to several hundreds of Torr. Then, a porous film is formed by a laser ablation method using the silicon contained in target 70 as a target.

Thus, when a laser beam L is output by a laser device 50, the laser beam L irradiates the target 70 via a focusing lens 23. Silicon (Si) constituting the target is ejected, as shown in FIG. 2, from target 70 in the portion thereof thus irradiated with laser.

The ejected silicon (Si) collides with oxygen, which is an atmosphere gas, and reacts therewith in a gas phase forming clusters composed of silicon (Si) and oxygen and containing pores with a size of several nanometers, or SiO₂ or SiOx.

The clusters adhere to substrate 60, thereby forming a porous film composed of Si and oxygen and containing pores on substrate 60. Thus, a porous insulating film is formed on substrate 60. The porosity, that is, the relative dielectric constant (or dielectric constant) of the porous insulating film changes depending on the film forming conditions such as: (1) energy intensity of laser, (2) pressure of atmosphere gas, (3) pressure of oxygen, (4) temperature of substrate (heater temperature), (5) distance between the substrate and the target, (6) laser irradiation angle, and the like.

As described above, the present invention, in accordance with the first aspect thereof, makes it possible to form a porous film with a low dielectric constant which is composed of silicon and oxygen and contains pores.

Furthermore, in accordance with the first aspect of the present invention, the porous film is formed without using a precursor solution. Therefore, the generation of a large amount of wastewater containing a precursor solution that was typical for the above-described conventional methods for forming porous films is prevented. As a result, a porous film can be formed by the environmentally friendly process and at a reduced cost.

Moreover, in accordance with the second aspect of the present invention a porous film with a low dielectric constant (in other words, a low relative dielectric constant) can be easily obtained.

Furthermore, in accordance with the third aspect of the present invention, the method for forming a porous film in accordance with the first aspect of the present invention is represented as another method claim. Therefore, the effects identical to those of the first aspect of the present invention can be obtained.

Furthermore, in accordance with the fourth aspect of the present invention, the method for forming a porous film in accordance with the second aspect of the present invention is represented as another method claim. Therefore, the effects identical to those of the second aspect of the present invention can be obtained.

In order to attain the above-described third object, in accordance with the fifth aspect of the present invention, a multilayer structure comprising an aggregate and a dense film is formed in an insulating film for a semiconductor element which is formed on a substrate, in the direction perpendicular to the surface of the substrate where the film is formed.

In the insulating film 100 for a semiconductor element in accordance with the fifth aspect of the present invention, a multilayer structure is formed in the direction perpendicular to the surface of substrate 60 where the film is formed in which, as shown in FIG. 3, an aggregate 110 is deposited and then a dense film 120 is formed.

The present invention, in accordance with the fifth aspect thereof, can provide an insulating film (interlayer film) for a semiconductor element with a low dielectric constant because the insulating film with a multilayer structure comprising a dense film and an aggregate with a high porosity has a low dielectric constant (small relative dielectric constant).

In accordance with the sixth aspect of the present invention, in the present invention in accordance with the fifth aspect thereof, the multilayer structure is formed which comprises an aggregate, a fine particle association, and a dense film.

In the insulating film 200 for a semiconductor element in accordance with the sixth aspect of the present invention, a multilayer structure is formed in the direction perpendicular to the surface of substrate 60 where the film is formed in which, as shown in FIG. 4, an aggregate 210 is deposited, then a fine particle association 220 is deposited, and then a dense film 230 is formed.

The present invention in accordance with the sixth aspect thereof makes it possible to obtain the same effects as the present invention in accordance with the above-described fifth aspect thereof. Furthermore, since in accordance with the sixth aspect of the present invention a fine particle association is introduced between the aggregate and the dense film, the bonding strength between the aggregate and the dense film can be improved by comparison with that attained in accordance with the fifth aspect of the present invention.

In accordance with the seventh aspect of the present invention, in the present invention in accordance with the fifth aspect thereof, the multilayer structure is formed which comprises a first dense film, an aggregate, and a second dense film.

In the insulating film 300 for a semiconductor element in accordance with the seventh aspect of the present invention, a multilayer structure is formed in the direction perpendicular to the surface of substrate 60 where the film is formed in which, as shown in FIG. 5, a dense film 310 (the aforesaid first dense film) is formed, then an aggregate 320 is deposited, and then a dense film 330 (the aforesaid second dense film) is formed.

The present invention in accordance with the seventh aspect thereof makes it possible to obtain the same effects as the present invention in accordance with the above-described fifth aspect thereof

In accordance with the eighth aspect of the present invention, in the present invention in accordance with the fifth aspect thereof, the multilayer structure is formed which comprises a first dense film, a first fine particle association, an aggregate, a second fine particle association, and a second dense film.

In the insulating film 400 for a semiconductor element in accordance with the eighth aspect of the present invention, a multilayer structure is formed in the direction perpendicular to the surface of substrate 60 where the film is formed in which, as shown in FIG. 6, a dense film 410 (the aforesaid first dense film) is formed, then a fine particle association 420 (the aforesaid first fine particle association) is deposited, then an aggregate 430 is deposited, thereafter a fine particle association 440 (the aforesaid second fine particle association) is deposited, and then a dense film 450 (the aforesaid second dense film) is formed.

The present invention in accordance with the eighth aspect thereof makes it possible to obtain the same effects as the present invention in accordance with the above-described fifth aspect thereof. Furthermore, since in accordance with the eighth aspect of the present invention fine particle associations are introduced between the aggregate and dense films, the bonding strength between the first dense film and the aggregate and between the aggregate and the second dense film can be improved by comparison to that attained in accordance with the seventh aspect of the present invention.

In accordance with the ninth aspect of the present invention, in the present invention in accordance with any, from fifth to eighth, aspect thereof, the aggregate of the multilayer structure is constituted by a columnar aggregate.

In the insulating film 500 for a semiconductor element in accordance with the ninth aspect of the present invention, a multilayer structure is formed in the direction perpendicular to the surface of substrate 60 where the film is formed in which, for example, as shown in FIG. 7, a columnar aggregate 510 is deposited and a dense film 520 is formed.

The present invention in accordance with the ninth aspect thereof makes it possible to obtain the same effects as the present invention in accordance with any, from fifth to eighth, aspect thereof. Furthermore, because in accordance with the ninth aspect of the present invention the insulating film comprises a columnar aggregate, an insulating film for a semiconductor element can be provided which has a porosity even higher, that is, a dielectric constant even lower (low relative dielectric constant) than that obtained with the present invention in accordance with the above-described fifth to eighth aspects thereof.

In accordance with the tenth aspect of the present invention, in the present invention in accordance with any, from fifth to ninth, aspect thereof, the internal portion of the aggregate is composed of fine particles.

Because in accordance with the tenth aspect of the present invention the internal portion of the aggregate is composed of fine particles, an insulating film for a semiconductor element can be provided which has a porosity even higher, that is, a dielectric constant even lower (low relative dielectric constant) than that obtained with the present invention in accordance with the above-described fifth to ninth aspects thereof

In accordance with the eleventh aspect of the present invention, in the present invention in accordance with any, from fifth to tenth, aspect thereof one dense film is formed at the very top of the multilayer structure.

Because in accordance with the eleventh aspect of the present invention the uppermost layer of the insulating film having a multilayer structure is formed of a dense film, an insulating film for a semiconductor element can be provided which has good adhesivity to substrate as well as a high mechanical strength and chemical resistance.

In order to attain the above-described third to fifth objects, the method for forming an insulating film for a semiconductor element in accordance with the twelfth aspect of the present invention is characterized in that a target and a substrate are disposed in a chamber, and, by changing the pressure of gas inside the chamber to a predetermined value, an insulating film is formed on the substrate by laser ablation of the target in the gas.

With the twelfth aspect of the present invention, when a single insulating film for a semiconductor element is formed, a multilayer structure allowing for a low dielectric constant (small relative dielectric constant) can be fabricated merely by changing the pressure of atmosphere gas during laser ablation.

A method for forming an insulating film for a semiconductor element in accordance with the thirteenth aspect of the present invention comprises a disposition step of disposing a target and a substrate in a chamber at a predetermined distance from each other, an introducing step of introducing a prescribed gas inside the chamber, a pressure transition step of causing a continuous transition of the pressure of gas inside the chamber introduced with the gas in the introducing step, and a film forming step of forming an insulating film on the substrate by irradiating a laser beam toward the target from outside of the chamber having the gas introduced therein by a laser ablation method in the course of continuous transition of the pressure inside the chamber in the pressure transition step.

The present invention according to the thirteenth aspect thereof relates to a method according to the twelfth aspect thereof considered from another viewpoint.

A method for forming an insulating film for a semiconductor element in accordance with the fourteenth aspect of the present invention is the method in accordance with the twelfth or thirteenth aspect of the present invention, wherein the insulating film is the insulating film for a semiconductor element described in any of claims 5 to 11.

With the insulating film for a semiconductor element in accordance with the fourteenth aspect of the present invention, the insulating film for a semiconductor element in accordance with the fifth to eleventh aspect of the present invention is formed by implementing laser ablation of the target in the atmosphere gas, while continuously changing the pressure of the atmosphere gas inside the chamber to the appropriate pressure value.

In order to attain the above-described first and second objects, with the method for forming a porous film in accordance with the fifteenth aspect of the present invention, a porous film composed of silicon and oxygen and containing pores is formed on a substrate by a laser ablation method using silicon as a target and conducted in a gas contains at least one oxidant component.

In accordance with the sixteenth aspect of the present invention, in the present invention in accordance with the fifteenth aspect thereof, the oxidant component contains at least one gas selected from the group consisting of O₂, N₂O and O₃.

In accordance with the seventeenth aspect of the present invention, in the porous film of the fifteenth and sixteenth aspects of the present invention, the relative dielectric constant of the porous film is adjusted so that it assumes the desired value.

In order to attain the above-described first and second objects, the method for forming a porous film in accordance with the eighteenth aspect of the present invention comprises a disposition step of disposing a target composed of silicon and a substrate inside a chamber at a predetermined distance from each other, an introducing step of introducing a gas contains at least one oxidant component inside the chamber, and a film forming step of forming a porous film consisting of silicon and oxygen and containing pores on the substrate by irradiating the target with a laser beam from outside of the chamber which has the gas containing at least one oxidant component introduced therein.

Furthermore, in accordance with the nineteenth aspect of the present invention, in the method of the eighteenth aspect of the present invention, the film forming step comprises a step of adjusting the relative dielectric constant of the porous film so that it assumes the desired value.

The invention according to the fifteenth aspect thereof will be described below with reference to FIG. 1 and FIG. 2.

As shown in FIG. 1, a substrate 60 and a target 70 are disposed opposite each other inside a vacuum, chamber 20. Vacuum chamber 20 is then evacuated with a vacuum pump 30, a gas inlet valve (not shown in the figure) is opened and, for example, oxygen is introduced into vacuum chamber 20 within a pressure range from several Torr to several hundreds of Torr. Then, a porous film is formed by a laser ablation method using the silicon contained in target 70 as a target.

Thus, when a laser beam L is output by a laser device 50, the laser beam L irradiates the target 70 via a focusing lens 23—Silicon (Si) constituting the target is ejected as shown in FIG. 2, from target 70 in the portion thereof thus irradiated with laser.

The ejected silicon (Si) collides with oxygen, which is an atmosphere gas, and reacts therewith in a gas phase forming clusters composed of silicon (Si) and oxygen and containing pores with a size of several nanometers, or SiO₂ or SiOx.

The clusters adhere to substrate 60, thereby forming a porous film composed of Si and oxygen and containing pores on substrate 60. Thus, a porous insulating film is formed on substrate 60, The porosity, that is, the relative dielectric constant (or dielectric constant) of the porous insulating film changes depending on the film forming conditions such as: (1) energy intensity of laser, (2) pressure of atmosphere gas, (3) pressure of oxidant component, (4) temperature of substrate (heater temperature), (5) distance between the substrate and the target, (6) laser irradiation angle, and the like.

As described above, the present invention, in accordance with the fifteenth aspect thereof, makes it possible to form a porous film with a low dielectric constant which is composed of silicon and oxygen and contains pores.

Furthermore, in accordance with the fifteenth aspect of the present invention, the porous film is formed without using a precursor solution. Therefore, the generation of a large amount of wastewater containing a precursor solution that was typical for the Above-described conventional methods for forming porous films is prevented. As a result, a porous film can be formed by the environmentally friendly process and at a reduced cost.

Moreover, in accordance with the sixteenth aspect of the present invention a porous film with a low dielectric constant (in other words, a low relative dielectric constant) can be easily obtained.

Furthermore, in accordance with the seventeenth aspect of the present invention, the method for forming a porous film in accordance with the fifteenth aspect of the present invention is represented as another method claim. Therefore, the effects identical to those of the fifteenth aspect of the present invention can be obtained.

Furthermore, in accordance with the eighteenth aspect of the present invention, the method for forming a porous film in accordance with the sixteenth aspect of the present invention is represented as another method claim. Therefore, the effects identical to those of the sixteenth aspect of the present invention can be obtained.

### BRIEF DESCRIPTION OF THE DRAWINGS

FIG. 1 is a structural view illustrating the structure of the apparatus for implementing the method for forming a porous film in accordance with the present invention;

FIG. 2 illustrates film forming by the method for forming a porous film in accordance with the present invention;

FIG. 3 is a cross-sectional schematic view of an insulating film for a semiconductor element in accordance with the present invention;

FIG. 4 is a cross-sectional schematic view of another insulating film for a semiconductor element in accordance with the present invention;

FIG. 5 is a cross-sectional schematic view of another insulating film for a semiconductor element in accordance with the present invention;

FIG. 6 is a cross-sectional schematic view of another insulating film for a semiconductor element in accordance with the present invention;

FIG. 7 is a cross-sectional schematic view of another insulating film for a semiconductor element in accordance with the present invention;

FIG. 8 is a cross-sectional schematic view of another insulating film for a semiconductor element in accordance with the present invention;

FIG. 9 is a structural view illustrating the structure of the apparatus for implementing the method for forming an insulating film for a semiconductor device in accordance with the present invention; and

FIGS. 10(a) to 10(c) illustrate forming of the insulating film during laser ablation depending on the difference in pressure of atmosphere gas inside the chamber.

### DESCRIPTION OF THE REFERRED EMBODIMENT

The preferred embodiment of the present invention will be described below with reference to the drawings attached.

First, a method for forming a porous film will be described.

In the present embodiment, a porous film composed of Si and oxygen and containing pores is formed on a substrate by a laser ablation method using silicon (referred to as Si hereinbelow) in a gas (atmosphere) containing oxygen.

In accordance with the laser ablation process, a thin film is formed by irradiating a target with a laser (laser beam), thereby heating the surface of the irradiated portion of the target to a high temperature and melting it, causing evaporation of this surface, and inducing the formation of clusters, thereby causing clusters to adhere to the substrate surface.

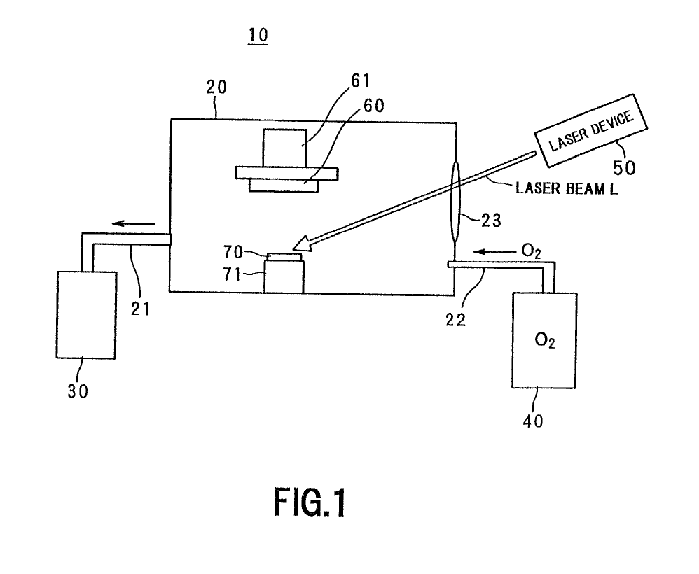

FIG. 1 is a structural view of an apparatus 10 for implementing the method for forming a porous insulating film in accordance with the present invention.

As shown in FIG. 1, apparatus 10 is generally composed of a vacuum chamber 20, a vacuum pump 30, a cylinder 40, a laser device 50, a substrate 60, and a target 70 composed of Si.

Substrate 60 held in a substrate holder 61 equipped with a heater and target 70 placed on a turntable 71 are disposed opposite each other at a prescribed distance from each other inside vacuum chamber 20.

Furthermore, vacuum chamber 20 is connected to vacuum pump 30 via a pipe 21 and to cylinder 40 via a pipe 22.

Cylinder 40 supplies oxygen. Only oxygen or gas comprising oxygen, such as a gaseous mixture of oxygen and nitrogen, may be supplied to vacuum chamber 20. Essentially, any gas (atmosphere gas) comprising oxygen that provides for gas-phase reaction of Si and oxygen may be used.

Furthermore, a focusing lens 23 focusing a laser beam emitted from laser device 50 onto a prescribed position of target 70 is attached to vacuum chamber 20.

An excimer laser device, a solid-state laser device, and the like may be used as laser device 50.

The distance between substrate 60 and target 70 and the irradiation angle of laser beam from laser device 50 are set to values allowing for the formation of a uniform insulating film on substrate 60.

A heater (not shown in the drawings) heating the substrate is provided inside support holder 61 provided with a heater. This heater is constructed so as to allow for post-annealing leading to the formation of a thin film of good quality by annealing the film, which was deposited at a low temperature, at a temperature of no less than crystallization temperature, or for as-deposition in which the substrate itself is maintained within the range of crystallization temperature during deposition and a thin film is formed which is crystallized in this field.

Turntable 71 can be rotated with a motor (not shown in the figures). Rotation of the turntable 71 can provide for uniform laser irradiation so as to prevent the formation of local craters occurring when the target is laser irradiated only in one and the same portion.

The operation of apparatus 10 will be described below.

First, substrate 60 and target 70 are disposed as described above, inside vacuum chamber 20, the vacuum chamber 20 is evacuated with vacuum pump 30, a valve (not shown in the figures) of cylinder 40 is opened and, for example, oxygen is introduced into vacuum chamber 20 under a pressure within a range from several Torr to several hundreds Torr. Furthermore, the heater of substrate holder 61 is timely heated according to the below-described film forming conditions. Then a porous film is formed by a laser ablation method using Si contained in target 70 as a target.

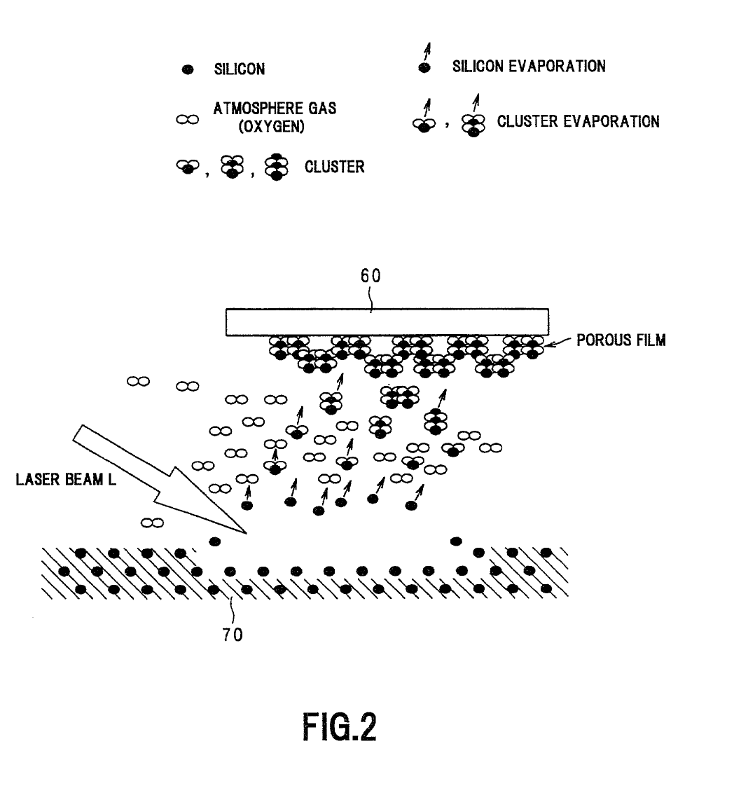

Thus, if laser beam L is emitted from laser device 50, the laser beam irradiates target 70 via focusing lens 23. Si constituting the target is ejected from target 70 in the portion thereof irradiated with laser beam, as shown in FIG. 2.

The ejected Si participates in gas-phase reaction with oxygen present in the atmosphere gas, while colliding therewith, and forms clusters composed of Si and oxygen and containing pores with a size of several nanometers, or SiO₂ or SiOx.

The clusters adhere to substrate 60, thereby forming a porous film (that is, porous insulating film) composed of Si and oxygen and containing pores on substrate 60. The porosity, that is, relative dielectric constant of the porous film changes depending on the below-described film forming conditions.

The conditions for forming the above-described porous film include: (1) energy intensity of laser, (2) pressure of atmosphere gas, (3) pressure of oxygen, (4) temperature of substrate (heater temperature), (5) distance between the substrate and target, (6) laser irradiation angle, and the like.

Among those conditions, conditions (5) and (6) provide for the formation of a uniform porous film on the substrate, and the values that were once set for the formation of a porous film on one substrate are not changed.

On the other hand, conditions (1)-(4) are employed for adjusting the porosity, that is, relative dielectric constant of the porous film to the desired values and are adjusted to the appropriate values in the formation of a porous film on one substrate.

The relative dielectric constant of a porous film is determined based on the number of pores in the film and the pore size (diameter of opening). For example, when the size of pores is constant, the larger is the number of pores, the smaller is the relative dielectric constant. On the other hand, when the number of pores is constant, the relative dielectric constant decreases with the increase in the pore size. Obviously, the value of relative dielectric constant decreases when the pore size is increased and the number of pores is also increased.

The size or number of pores which are important factors for decreasing the value of relative dielectric constant of a porous film can be controlled by adjusting the above-described (1) energy intensity of laser, (2) pressure of atmosphere gas, (3) pressure of oxygen, and (4) temperature of substrate (heater temperature).

For example, the size of the above-mentioned clusters, and the film formation rate can be controlled by adjusting the energy intensity of laser beam from laser device 50 (aforesaid condition 1), pressure of atmosphere gas inside vacuum chamber 20 (aforesaid condition 2, and pressure of oxygen from cylinder 40 (aforesaid condition 3). Therefore, the number of pores in the film or the size of pores can be thus increased. As a result, the value of relative dielectric constant of the formed porous film can be decreased.

The relative dielectric constant of the porous film can be determined, for example, by measuring the electrostatic capacitance of the porous film formed on substrate 60, for example, with an LCR motor and conducting calculations by using values of surface area and thickness of the porous film on which the measurements have been conducted.

In the above-described embodiment, substrate 60 disposed opposite to target 70 was secured. The present invention is, however, not limited to such configuration and substrate holder 61 equipped with a heater and holding substrate 60 may also be rotated in the prescribed direction with a drive motor (not shown in the figures). As a result, the porous film formed on substrate 60 can be formed even more uniformly.

Furthermore, in the above-described embodiment, substrate 60 and target 70 were disposed opposite to each other. However, the present invention is not limited to such configuration and the following configuration may also be used.

Thus, target 70 is maintained in the present state, substrate 60 is disposed at an angle of 90° to target 70, and holder 61 equipped with a heater and holding substrate 60 is rotated in the prescribed direction with a drive motor (not shown in the figures).

In this case, it is preferred that the surface of substrate 60 disposed at an angle of 90° where the porous film is to be formed (referred to as film forming surface hereinbelow) be present on an extension line perpendicular to the surface of target 70 which is irradiated with laser beam, in other words, in a space obtained when the irradiation surface is moved parallel to itself from the present position to a position close to substrate 60.

Furthermore, substrate 60 may also be disposed at an angle of 90° to target 70 outside the above-mentioned space inside the range in which clusters can be adhered to the film forming surface of substrates 60 as described above, by laser ablation of target 70.

Moreover, similarly to the above-described configuration, the film forming surface of substrate 60 may also be disposed at a predetermined angle to target 70 within the range in which clusters can adhere to the film forming surface of substrate 60. In this case the film forming surface of substrate 60 is preferably disposed at an acute angle to target 70.

After substrate 60 has been disposed at a present angle, for example, at an angle of 90° to target 70, substrate holder 61 equipped with a heater is rotated in the predetermined direction by a drive motor (not shown in the figures) during ablation treatment of target 70, thereby rotating substrate 60 held by substrate holder 61 equipped with a heater and providing for uniformity of the porous film that is formed on substrate 60.

As described above, with the present embodiment, a porous film composed of Si and oxygen and containing pores is formed on a substrate by a laser ablation method using Si as a target in an atmosphere containing oxygen. Therefore, the following effects can be expected.

(1) The cluster size and film formation rate can be controlled by changing the film forming conditions, for example, atmosphere gas pressure inside the chamber or energy intensity (density) of laser. As a result, the relative dielectric constant of the porous film (porous insulating film) can be adjusted.

In particular, when the adjustment is conducted so as to increase the porosity of the porous film, a porous film (porous insulating film) with a relative dielectric constant of 1.5 which is required for semiconductor processes of the next generation can be formed.

(2) Furthermore, changing porosity of the porous film means changing the number or size of pores in the porous film. Therefore, the strength of the porous film related to those parameters can be adjusted according changes in those parameters. In other words, the strength of the porous film can be adjusted by adjusting the porosity of the porous film.

(3) Furthermore, the method for forming a porous film by an ablation process is inherently different from the conventional method in which a precursor solution was coated on a substrate. Therefore, issues relating to the preparation of precursor solution and degradation of the precursor solution with time as a result of chemical transformations thereof may not be taken into account.

Moreover, the relative dielectric constant of the porous film can be adjusted (for example, relative dielectric constant 1.5) by changing film forming conditions such as pressure of atmosphere gas inside the chamber and energy intensity (density) of laser. Therefore, film forming conditions conforming to a semiconductor process are easily changed without preparing the precursor solution, as in the conventional processes.

(4) Another merit is that materials (for example, SiO2) that have been used heretofore serve as materials of the porous film produced by the method for forming a porous film by an ablation process. Therefore, the number of technological problems relating to a semiconductor fabrication process that are raised by the method for forming a porous film is small.

The insulating film for a semiconductor element and a method for forming such insulating film will be described below.

In the present embodiment, a target and a substrate are disposed inside a chamber and laser ablation of the target is conducted in an atmosphere gas, while continuously changing the pressure of the atmosphere gas inside the chamber, thereby forming an insulating film with a multilayer structure on the substrate.

In accordance with the laser ablation process, a thin film is formed by irradiating a target with a laser (laser beam), thereby heating the surface of the irradiated portion of the target to a high temperature and melting it, causing evaporation of this surface, and inducing the formation of clusters, thereby causing clusters to adhere to the substrate surface.

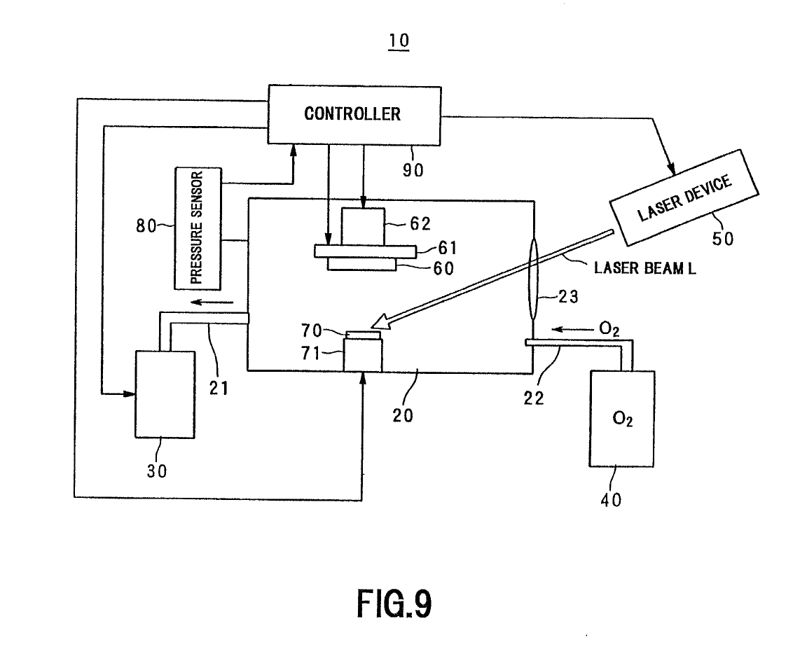

FIG. 9 is a structural view of an apparatus 10 for implementing the method for forming a porous insulating film for a semiconductor element in accordance with the present invention.

As shown in FIG. 9, apparatus 10 is generally composed of a vacuum chamber 20, a vacuum pump 30, a cylinder 40, a laser device 50, a substrate 60, a target 70, a pressure sensor 80, and a controller 90.

Substrate 60 held in a substrate holder 61 equipped with a heater and target 70 placed on a turntable 71 are disposed opposite each other at a prescribed distance from each other inside vacuum chamber 20. Furthermore, vacuum chamber 20 is connected to vacuum pump 30 via a pipe 21 and to cylinder 40 via a pipe 22. Furthermore, a focusing lens 23 focusing a laser beam emitted from laser device 50 onto a prescribed position of target 70 is attached to vacuum chamber 20.

The distance between substrate 60 and target 70 (referred to as target-substrate distance hereinbelow) and the irradiation angle of laser beam from laser device 50 are set to values allowing for the formation of a uniform insulating film on substrate 60.

Pressure of the atmosphere gas inside vacuum chamber 20 is adjusted with vacuum pump 30 by opening a valve (not shown in the figures).

When the valve (not shown in the figures) is opened, oxygen is supplied from cylinder 40 to vacuum chamber 20. Only oxygen or gas comprising oxygen, such as a gaseous mixture of oxygen and nitrogen, may be supplied to vacuum chamber 20.

An excimer laser device, such as KrF excimer laser or ArF excimer laser, a solid-state laser device, and the like may be used as laser device 50.

Substrate holder 61 equipped with a heater holds substrate 60 in a state in which substrate holder 61 is attached to movable stage 62. A heater (not shown in the drawings) for heating substrate 60 is provided inside support holder 61. This heater is constructed so as to allow for post-annealing leading to the formation of a thin film of good quality by annealing the film, which was deposited at a low temperature, at a temperature, or for the formation of a thin film of good quality by maintaining the substrate itself during deposition within a prescribed temperature range.

A movable stage 62 can be moved in the X axis direction, Y axis direction, and Z axis direction (vertical direction). The insulating film can be formed within the desired range of substrate 60 by moving movable stage 62 in the X axis and Y axis directions. The distance between substrate 60 and target 70 can be adjusted by moving movable stage in the Z axis direction.

Turntable 71 can be rotated by a motor (not shown in the figures). Rotation of turntable 71 can provide for uniform laser irradiation so as to prevent the formation of local craters occurring when the target is laser irradiated only in one and the same portion.

Pressure sensor 80 detects a pressure of atmosphere gas inside vacuum chamber 20 and outputs the detected pressure value to controller 90.

Controller 90 controls vacuum pump 30, laser device 50, substrate holder 61 equipped with a heater, movable stage 62, and turntable 71 according to film forming conditions. For example, a command relating to the desired pressure is output to vacuum pump 30 based on the pressure value from pressure sensor.

In the present embodiment, target 70 is composed of a material constituted by silicon (Si).

The following parameters serve as the conditions for forming an insulating film for a semiconductor element: (1) atmosphere gas (type and pressure), (2) energy intensity (energy density) of laser, (3) laser pulse frequency, (4) temperature of substrate (heater temperature), (5) target-substrate distance, (6) laser irradiation angle, (7) shot number of laser, and the like.

Among those parameters, the aforesaid parameter (6) provides for the formation of a uniform insulating film on the substrate, and the value that was once set for the formation of an insulating film on one substrate is not changed.

On the other hand, conditions (1)-(5) and (7) are employed for adjusting the porosity, that is, relative dielectric constant of the insulating film to the desired values and are adjusted to the appropriate values in the formation of an insulating film on one substrate.

An example of the method for forming an insulating film for a semiconductor element with apparatus 10 will be described below with reference to FIG. 9.

(1) Disposition Step

First, substrate 60 and target 70 are disposed at the predetermined distance from each other inside vacuum chamber 20. The arrangement of substrate 60 and target 70 and the irradiation angle of laser are such as to provide for the formation of a uniform insulating film on substrate 60. The heater located in substrate holder 61 is timely heated according to the above-described film forming conditions.

(2) Introducing Step

Then, vacuum chamber 20 is evacuated by vacuum pump 30 according to command from controller 90. A valve (not shown in the figures) of cylinder 40 is thereafter opened and a gas (for example, oxygen) is introduced in vacuum chamber 20 to a pressure within a range from several Torr to several hundreds Torr.

(3) Pressure Transition Step

A continuous transition of pressure of atmosphere gas inside vacuum chamber 20 filled with the gas (atmosphere gas) in the introducing step is caused by vacuum pump 30 according to a command from controller 90 determined based on the information relating to pressure value from pressure sensor 80 and the predetermined film forming conditions.

The pressure transition state includes the state of the pressure under which a dense film can be formed (referred to as the first pressure), state of the pressure under which an aggregate can be formed (referred to as the second pressure), and the state of the pressure between the first pressure and second pressure (referred to as the third pressure).

Furthermore, in the pressure transition step, the pressure can be changed rapidly or gradually from the first pressure to the second pressure, or from the second pressure to the first pressure.

(4) Film Forming Step

Laser ablation by irradiating target 70 with laser radiation from laser device 50 is implemented in a state in which the pressure inside vacuum chamber 20 was changed to the pressure transition states in the pressure transition step, and an insulating film is produced which has a structure corresponding to the pressure in each pressure transition state, as described in detail below.

Thus, under the pressure in the above-described transition states, an insulating film is formed on substrate 60 by a laser ablation method in which laser beam L is irradiated from laser device 50 disposed outside of vacuum chamber 20 toward target 70.

Obviously, besides the adjustment of atmosphere gas pressure inside vacuum chamber 20, the adjustment of values of parameters (2)-(5), (7) as the film forming conditions will also result in a different structure of the insulating film for a semiconductor element. Therefore, if necessary, laser ablation is implemented by adjusting values of parameters (2)-(5), (7) as the film forming conditions.

Here, when parameter (2) which is the value of energy intensity (energy density) of laser, parameter (3) which is the value of laser cycle frequency, or parameter (7) which is the value of the number of laser shots is adjusted, controller 90 outputs to laser device 50 the desired energy intensity, or the desired laser cycle frequency, or the number of laser shots, or data indicating the variations thereof as well as the command requiring the adjustment of energy intensity, or frequency, or the number of shots.

When parameter (4) which is the value of substrate temperature (heater temperature) is adjusted, controller 90 outputs to substrate holder 61 equipped with a heater the data indicating the desired temperature or temperature variations as well as the command requiring the adjustment of temperature.

Furthermore, when parameter (5) which is the value of the target-substrate distance is adjusted, controller 90 outputs to movable stage 62 the data indicating the amount of movement in the Z axis direction (vertical direction) as well as the command requiring the movement.

It is known that when laser ablation is implemented in a transition states in which the pressure was changed to each of the above-described first pressure, second pressure, and third pressure, insulating films with different structures will be formed under pressures in each of the transition state.

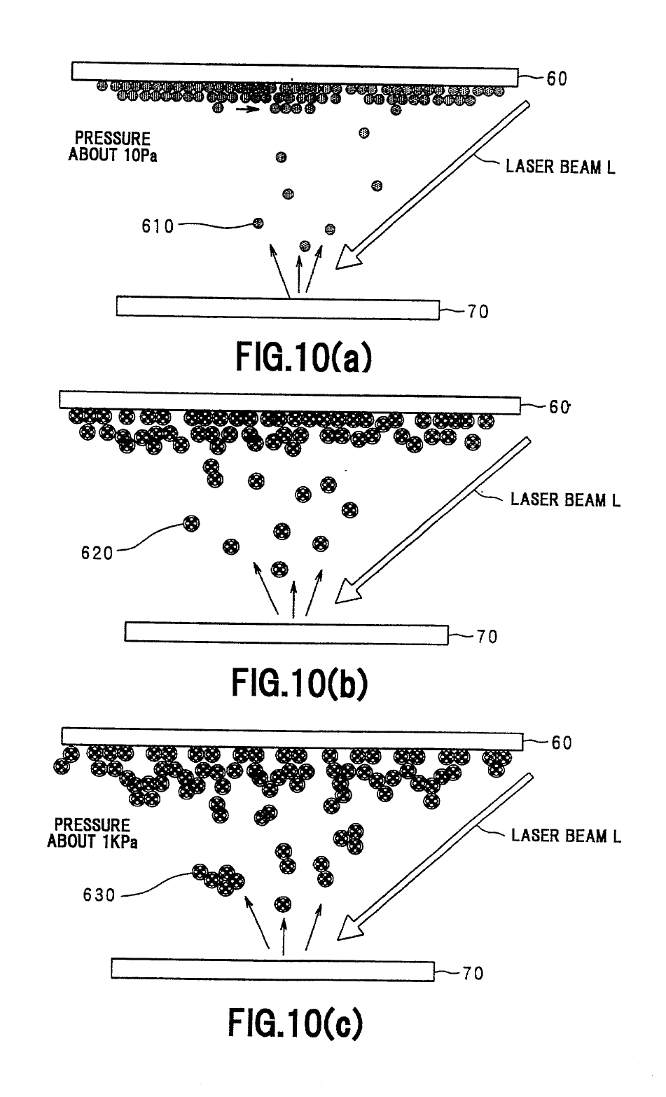

Insulating films which differ depending on the difference in the pressure of atmosphere gas will be described below with reference to FIG. 10.

If during ablation the pressure of atmosphere gas (aforesaid first pressure) inside vacuum chamber 20 is low and a mean free range is sufficiently long by comparison with the target-substrate distance, the atoms and molecules directly reach the substrate, without colliding with other atoms and molecules, and, as shown in FIG. 10(a), atoms and molecules 610 that reached substrate 60 migrate over substrate 60 and form a film of increased density (referred to as a dense film) on substrate 60.

Furthermore, if during the ablation the pressure of atmosphere gas inside vacuum chamber 20 become higher (aforesaid third pressure) than the first pressure, as shown in FIG. 10(b), atoms and molecules cohere, form fine particles (in other words, fine particle association) 620, and reach substrate 60. Thus, fine particles (in other words, fine particle association) 620 are deposited on substrate 60.

Moreover, if during the ablation the pressure of atmosphere gas inside vacuum chamber 20 is further increased (aforesaid second pressure) and the mean free range becomes sufficiently short by comparison with the target-substrate distance, as shown in FIG. 10(c), fine particles collide with molecules of atmosphere gas and lose kinetic energy. The fine particles are then combined into an aggregate 630 which is deposited on substrate 60. The higher is the pressure of the atmosphere gas, the larger is the size of aggregate 630.

More specifically, if a film is formed by laser ablation in the atmosphere gas comprising oxygen by using silicon (Si) as a target under the above-described pressures, then a SiO₂ film is obtained. Thus, when clusters composed of silicon (Si) and oxygen and containing pores adhere to substrate 60 a film composed of silicon (Si) and oxygen and containing pores, for example, a SiO₂ film is formed on substrate 60.

In the below described present embodiment, the state with a pressure at which aggregate 630 can be formed (corresponds to aforesaid second pressure), for example, about 1 KPa (units: kilopascals) will be referred to as pressure transition state 1, pressure at which fine particle association 620 can be formed (corresponds to aforesaid third pressure) will be referred to as pressure transition state 2, and pressure at which a dense film (a dense film formed only by atoms and molecules 610) can be formed (corresponds to aforesaid first pressure), for example, about 10 Pa (units: pascals) will be referred to as pressure transition state 3.

Various insulating films that can be formed by the above-described method for forming an insulating film for a semiconductor element will be described below.

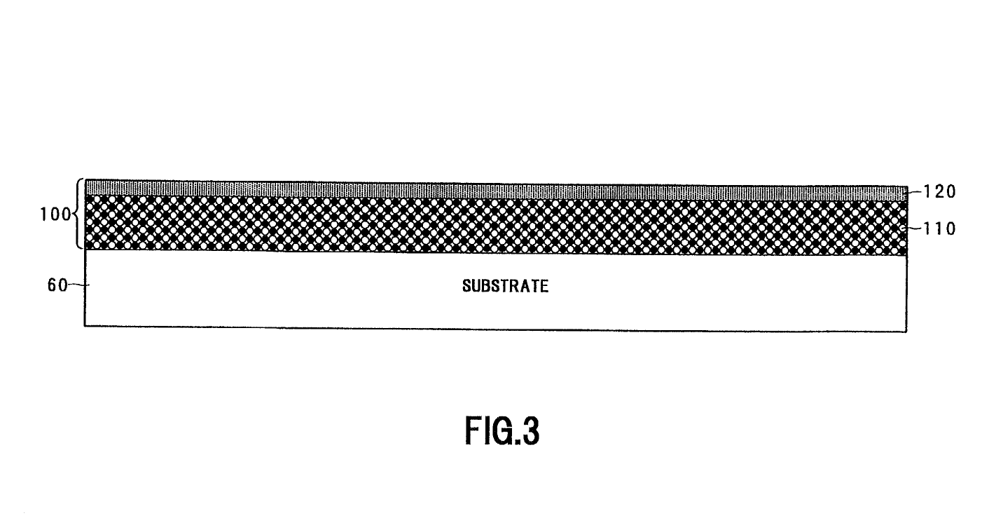

FIGS. 3 to 8 are cross-sectional schematic views of insulating films for semiconductor elements of the embodiment of the present invention.

Here, various insulating films for semiconductor elements will be described together with specific methods for forming thereof. Furthermore, a case will be assumed in which a SiO₂ film is formed as an insulating film for a semiconductor element by implementing laser ablation using silicon (Si) as a target in an atmosphere gas composed of oxygen.

As shown in FIG. 3, an insulating film 100 for a semiconductor element was formed to have a multilayer structure in which an aggregate 110 was deposited in the direction perpendicular to the surface of substrate 60 where the film was formed and then a dense film 120 was formed.

With the method for forming an insulating film employed in this case, first, aggregate 110 is produced by implementing laser ablation under a pressure (for example, 1 KPa) of atmosphere gas inside vacuum chamber 20 of pressure transition state 1. Then, a transition is made from the pressure of pressure transition state 1 to a pressure of pressure transition state 3 (for example, 10 Pa), and dense film 120 is produced by implementing laser ablation by adjusting values of parameter (2)-(5), (7) as the above-mentioned film forming conditions under the pressure of the pressure transition state 3.

The thickness of each layer in the multilayer structure constituted by aggregate 110 and dense film 120 and the thickness ratio of the layer are adjusted, for example, by adjusting the number of times the target 70 is irradiated with a laser beam from laser device 50.

The insulating film 100 thus formed has a multilayer structure in which the upper surface of aggregate 110 is covered with dense film 120. In other words, the structure discontinuously changes from aggregate 110 to dense film 120.

In such insulating film 100 for a semiconductor element, since pores are formed, in particular, in aggregate 110, the dielectric constant (relative dielectric constant) can be decreased.

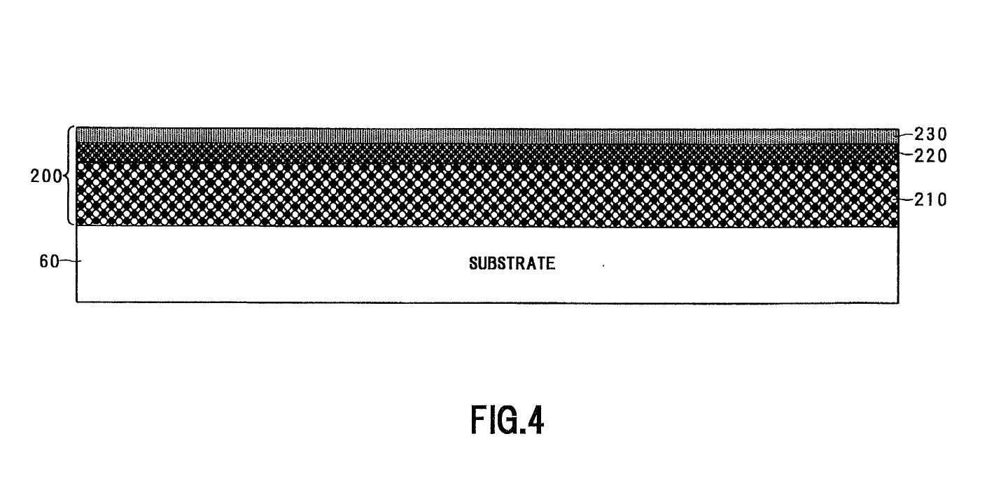

As shown in FIG. 4, an insulating film 200 for a semiconductor element was formed to have a multilayer structure in which an aggregate 210 was deposited in the direction perpendicular to the surface of substrate 60 where the film was formed, then a film particle association 220 was deposited, and then a dense film 230 was formed.

With the method for forming an insulating film employed in this case, first, aggregate 210 is produced by implementing laser ablation under a pressure (for example, 1 KPa) of atmosphere gas inside vacuum chamber 20 of pressure transition state 1.

Then, a transition is gradually made from the pressure of pressure transition state 1 to a pressure of pressure transition state 3 (about 10 Pa). In such case, since a gradual transition is made from pressure transition state 1 to pressure transition state 3, the pressure transition state 2 is present in this transition step. Fine particle association 220 is deposited on aggregate 210 by implementing laser ablation under a pressure of the pressure transition state 2.

Then, when a transition is made from pressure transition state 2 to pressure transition state 3, dense film 230 is produced by implementing laser ablation by adjusting values of parameters (2)-(5), (7) as the above-mentioned film forming conditions under the pressure of the pressure transition state 3 (for example, 10 Pa).

The thickness of each layer in the multilayer structure constituted by aggregate 210, fine particle association 220, and dense film 230 and the thickness ratio of the layers are adjusted, for example, by adjusting the number of times the target 70 is irradiated with a laser beam from laser device 50.

The insulating film 200 thus formed has a multilayer structure in which the upper portion of aggregate 210 gradually changes into dense film 230 and the fine particle association 220 is introduced therebetween. In other words, the structure continuously changes from aggregate 210 to dense film 230.

In such insulating film 200 for a semiconductor element, since the fine particle association is introduced between the aggregate and the dense film, the two layers are connected continuously and, though the dielectric constant (relative dielectric constant) increases by comparison with the case of insulating film 100, bonding strength between the aggregate and the dense film is increased.

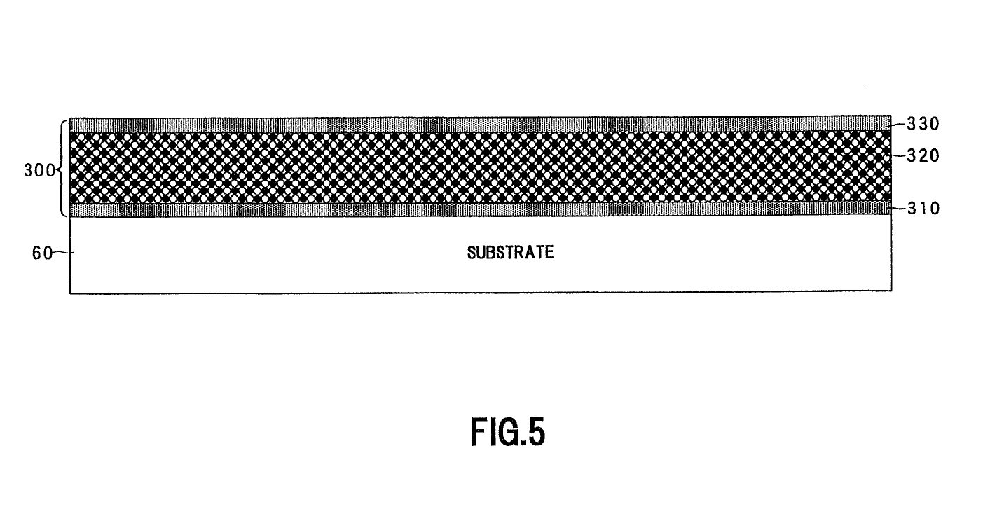

As shown in FIG. 5, an insulating film 300 for a semiconductor element was formed to have a multilayer structure in which a dense film 310 was formed in the direction perpendicular to the surface of substrate 60 where the film was formed, then an aggregate 320 was deposited, and then a dense film 330 was formed.

With the method for forming an insulating film employed in this case, first, dense film 310 is produced by implementing laser ablation under a pressure (for example, 10 Pa) of atmosphere gas inside vacuum chamber 20 of pressure transition state 3.

Then, a transition is made from the pressure of pressure transition state 3 to a pressure of pressure transition state 1 (for example, 1 KPa), and aggregate 320 is produced by implementing laser ablation by adjusting values of parameters (2)-(5), (7) as the above-mentioned film forming conditions under the pressure of the pressure transition state 1.

A transition is thereafter made from the pressure of pressure transition state 1 to a pressure of pressure transition state 3 (for example, 10 Pa), and dense film 330 is produced by implementing laser ablation by adjusting values of parameters (2)-(5), (7) as the above-mentioned film forming conditions under the pressure of pressure transition state 3.

The thickness of each layer in the multilayer structure constituted by dense film 310, aggregate 320, and dense film 330 and the thickness ratio of the layers are adjusted, for example, by adjusting the number of times the target 70 is irradiated with a laser beam from laser device 50.

The insulating film 300 thus formed has a multilayer structure in which the upper and lower surfaces of aggregate 320 are covered with dense films 310, 330. In other words, the structure discontinuously changes from aggregate 320 to dense films 310, 330.

In such insulating film 300 for a semiconductor element, since pores are formed, in particular, in aggregate 320, the dielectric constant (relative dielectric constant) can be decreased.

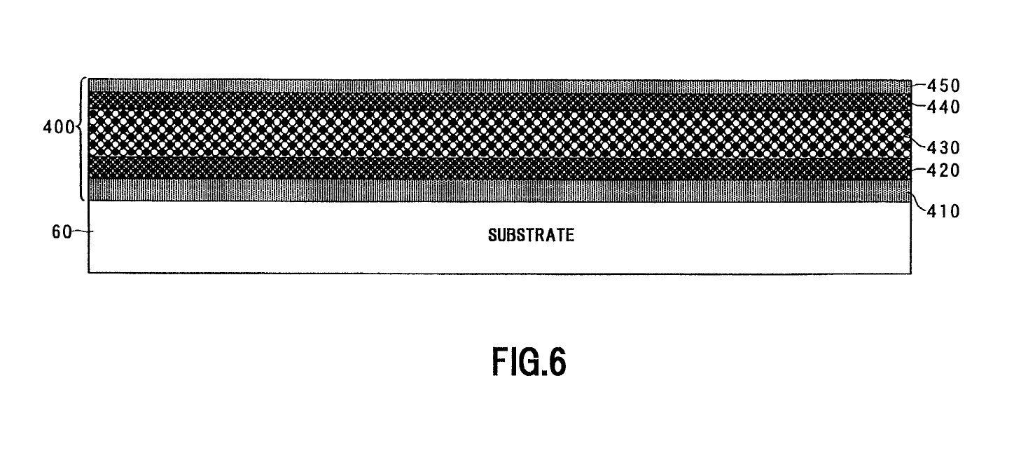

As shown in FIG. 6, an insulating film 400 for a semiconductor element was formed to have a multilayer structure in which a dense film 410 was formed in the direction perpendicular to the surface of substrate 60 where the film was formed, then a film particle association 420 was deposited, then an aggregate 430 was deposited, thereafter a film particle association 440 was deposited, and then a dense film 450 was formed.

With the method for forming an insulating film employed in this case, first, dense film 410 is produced by implementing laser ablation under a pressure (for example, 10 Pa) of atmosphere gas inside vacuum chamber 20 of pressure transition state 3.

Then, a transition is gradually made from the pressure of pressure transition state 3 to a pressure of pressure transition state 1 (for example, 1 KPa). In such case, since a gradual transition is made from pressure transition state 3 to pressure transition state 1, the pressure transition state 2 is present in this transition step. Fine particle association 420 is deposited on dense film 410 by implementing laser ablation under a pressure of pressure transition state 2.

Then, when a transition is made from pressure transition state 2 to pressure transition state 1, aggregate 430 is produced by implementing laser ablation by adjusting values of parameters (2)-(5), (7) as the above-mentioned film forming conditions under the pressure of pressure transition state 1 (for example, 1 KPa).

The pressure of pressure transition state 1 (for example 1 KPa) is then gradually changed to a pressure of pressure transition state 3 (for example, 10 Pa). In this case, since a transition is gradually made from pressure transition state 1 to pressure transition state 3, the pressure transition state 2 is present in this transition step similarly to the above-described step. Fine particle association 440 is deposited on aggregate 430 by implementing laser ablation under the pressure of pressure transition state 2.

When a transition is then made from pressure transition state 2 to pressure transition state 3, dense film 450 is produced by implementing laser ablation by adjusting values of parameters (2)-(5), (7) as the above-mentioned film forming conditions under the pressure of the pressure transition state 3 (for example, 10 Pa).

The thickness of each layer in the multilayer structure constituted by dense film 410, fine particle association 420, aggregate 430, fine particle association 440, and dense film 450 and the thickness ratio of the layers are adjusted, for example, by adjusting the number of times the target 70 is irradiated with a laser beam from laser device 50.

The insulating film 400 thus formed has a multilayer structure in which the upper and lower portions of aggregate 430 gradually change into dense films 410, 450 and fine particle associations 420, 440 are introduced therebetween in the upper and lower portions. In other words, the structure continuously changes from aggregate 430 to dense films 410, 450.

In such insulating film 400 for a semiconductor element, since fine particle associations are introduced between the aggregate and the dense films, the two layers are connected continuously and, though the dielectric constant (relative dielectric constant) increases by comparison with the case of insulating film 300, bonding strength between the aggregate and dense films is increased.

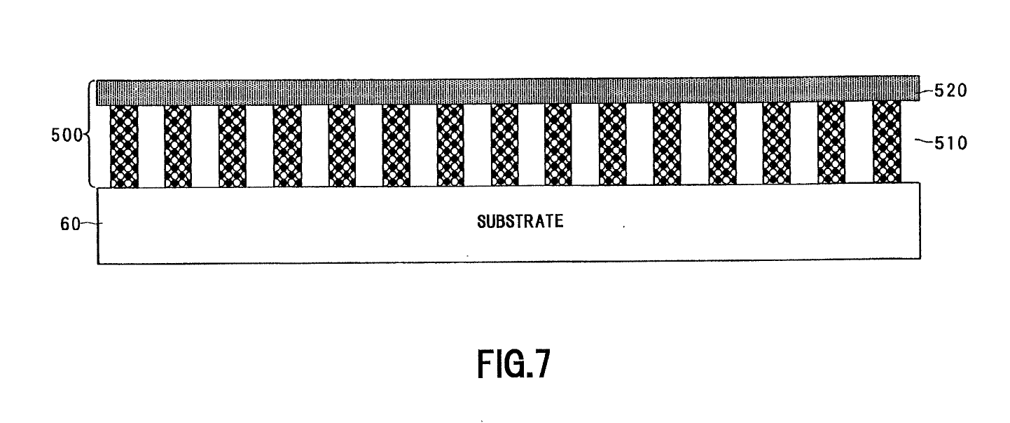

As shown in FIG. 7, an insulating film 500 for a semiconductor element was formed to have a multilayer structure in which a columnar aggregate 510 was deposited in the direction perpendicular to the surface of substrate 60 where the film was formed and then a dense film 520 was formed.

With the method for forming an insulating film employed in this case, first, columnar aggregate 510 is produced by implementing laser ablation by adjusting values of parameters (2)-(5), (7) as the above-mentioned film forming conditions under a pressure of atmosphere gas inside vacuum chamber 20 which allows for the formation of columnar aggregate 510.

Then, a transition is made from the pressure which allows for the formation of columnar aggregate 510 to pressure transition state 3 and a dense film 520 is produced by implementing laser ablation by adjusting values of parameters (2)-(5), (7) as the above-mentioned film forming conditions under a pressure of pressure transition state 3 (for example, 10 Pa).

The thickness of each layer in the multilayer structure constituted by aggregate 510 and dense film 520 and the thickness ratio of the layers are adjusted, for example, by adjusting the number of times the target 70 is irradiated with a laser beam from laser device 50.

In such insulating film 500 for a semiconductor element, the porosity of columnar aggregate 510 is higher, for example, that that of aggregate 110 in the above-described insulating film 100. Therefore, dielectric constant (relative dielectric constant) can be substantially decreased by comparison with that of the insulating film 100.

Insulating film 500 for a semiconductor element shown in FIG. 7 is equivalent to the insulating film 100 for a semiconductor element shown in FIG. 3 in which aggregate 110 is changed to a columnar aggregate. Therefore, in the insulating films for semiconductor elements that are shown in FIGS. 4 to 6, multilayer structures can be obtained in which the aggregate of the respective insulating films is changed to a columnar aggregate by implementing the above-described step of the preparation of columnar aggregate 510.

When in the above-described insulating films 200, 300, 400 columnar aggregates are produced instead of aggregates, the porosity is increased by comparison with that of the insulating films 200, 300, 400. Therefore, the dielectric constant (relative dielectric constant) can be greatly decreased.

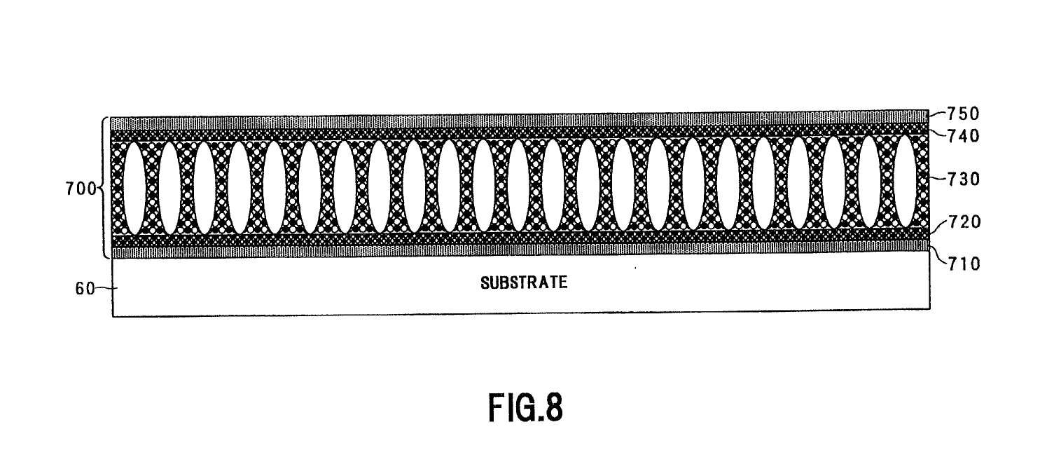

Besides the columnar aggregate 500 shown in FIG. 7, the columnar aggregate shown in FIG. 8 can be also produced as the columnar aggregate.

Thus, as shown in FIG. 8, an insulating film 700 for a semiconductor element was formed to have a multilayer structure in which a dense film 710 was produced in the direction perpendicular to the surface of substrate 60 where the film was formed, then a fine particle association 720 was deposited, thereafter a columnar aggregate 730 was deposited, then a fine particle association 740 was deposited, and thereafter a dense film 750 was produced.

In the method for forming an insulating film in this case, parameters such as pressure are gradually changed when an insulating film having a columnar aggregate is produced. Thus, by manufacturing insulating film 700 with a multiyear structure such as shown in FIG. 8, it is possible to increase porosity and also strength and to form a stable dense film.

In the insulating film with a multilayer structure having an aggregate with the internal portion thereof composed of fine particles, porosity can be increased by comparison with the aggregates (aggregates in which the inside portion is not composed of fine particles) of insulating films 100-500. Therefore, dielectric constant (relative dielectric constant) can be decreased even greater by comparison with that of insulating films 100-500.

In the above-described insulating films for semiconductor elements, dielectric constant (or relative dielectric constant), flatness of the insulating film surface, and bonding strength between layers (structures) in the multilayer structure differ depending on the structure thereof Therefore, if necessary, an appropriate structure is selected when the insulating films for semiconductor elements are formed.

Furthermore, in the above-described embodiments, as assumption was made that a SiO₂ (silicon dioxide) film is formed as an insulating film for a semiconductor element by implementing laser ablation with silicon (Si) as a target in the atmosphere gas composed of oxygen. The present invention, however, is not limited to such embodiment thereof and the following implementation is also possible.

Thus, since laser ablation is not selective with respect to the target or atmosphere gas, laser ablation is implemented with another target or under another atmosphere gas. Therefore, low dielectric films such as SiOF (fluorine-added silicon oxide), SiOC (carbon-added silicon oxide), CF (fluorocarbon), organic films, and the like can be produced.

With the present embodiments, as described above, insulating films for semiconductor devices with multilayer structures were obtained those structures being composed of a dense film and an aggregate with a high porosity. Therefore, the following effect can be expected.

(1) An insulating film serving as an interlayer insulating film for a semiconductor element with a low relative dielectric constant (that is, low dielectric constant) can be formed and provided by producing an aggregate having a porosity of no less than 20%. For example, if a structure is produced in which spherical fine particle associations which are filled inside thereof (all of the fine particle associations are assumed to have the same radius), a porosity of about 26% is obtained. The porosity can be further increased by producing even sparser structure.

In particular, when the aggregate is in the form of a columnar aggregate or an aggregate having the inner portion thereof composed of fine particles, an insulating film for a semiconductor element can be formed and provided which has a porosity further increased by comparison with the above-described case and which has an even lower relative dielectric constant.

Thus, an insulating film (interlayer insulating film) for a semiconductor element can be formed and provided which has a relative dielectric constant of 1.5 that is required for the next generation semiconductor processes that will apparently use a 0.07 gm design rule.

(2) Furthermore, since the upper layer of the insulating film with a multilayer structure if formed of a dense film, a film with good bonding strength and also high mechanical strength and chemical resistance can be obtained.

(3) Moreover, when an insulating film for one semiconductor element is formed, a multilayer structure allowing for a low dielectric constant (small relative dielectric constant) can be continuously produced merely by changing the conditions, such as atmosphere gas pressure, during laser ablation (PLD).

In this case, the thickness of each layer constituting the multilayer structure, for example, a dense film, an aggregate, and a fine particle association, and the thickness ratio of the layers can be accurately adjusted by adjusting the number of times the target 70 is irradiated with a laser beam from laser device 50.

(4) Furthermore, an insulating film with a low dielectric constant can be formed as an interlayer insulating film for a semiconductor element by using one chamber (one vacuum chamber 20). Therefore, the apparatus for the formation of interlayer insulating films for semiconductor elements is simplified.

By contrast, in the above-described conventional apparatus (the above-described openly described apparatus), a multimodule system provided with a plasma CVD chamber and a plasma etching chamber had to be used for forming an interlayer film with a three-layer structure. Moreover, an apparatus was required for transporting semiconductor substrates to be treated between the chambers. and the entire apparatus was complex.

What is claimed is:

1. A method for forming a porous film by which a porous film composed of silicon and oxygen and containing pores is formed on a substrate by a laser ablation method employing silicon as a target in a gas comprising oxygen.

2. The method for forming a porous film according to claim 1, wherein the relative dielectric constant of said porous film is adjusted so as to assume a desired value.

3. A method for forming a porous film comprising.
a disposition step of disposing a target comprising silicon and a substrate in a chamber at a predetermined distance from each other;
an introducing step of introducing a gas comprising oxygen inside said chamber, and
a film forming step of forming a porous film composed of silicon and oxygen and containing pores on said substrate by irradiating a laser beam toward said target from outside of the chamber having said gas comprising oxygen introduced therein, by a laser ablation method.

4. The method for forming a porous film according to claim 3, wherein
said film forming step comprises a step of adjusting the relative dielectric constant of said porous film so as to obtain a desired value.

5. An insulating film for a semiconductor element formed on a substrate, wherein a multilayer structure composed of an aggregate and a dense film is formed in a direction perpendicular to a surface of said substrate where the film is formed.

6. The insulating film for a semiconductor element according to claim 5, wherein said multilayer structure is formed to have an aggregate, a fine particle association, and a dense film.

7. The insulating film for a semiconductor element according to claim 5, wherein said multilayer structure is formed to have a first dense film, an aggregate, and a second dense film.

8. The insulating film for a semiconductor element according to claim 5, wherein sad multilayer structure is formed to have a first dense film, a first fine particle association, an aggregate, a second fine particle association, and a second dense film.

9. The insulating film for a semiconductor element according to any of claims 5 to 8, wherein the aggregate of said multi layer structure is composed of a columnar aggregate.

10. The insulating film for a semiconductor element according to any of claims 5 to 9, wherein said aggregate has an inner portion thereof composed of fine particles.

11. The insulating film for a semiconductor element according to any of claims 5 to 10, wherein one dense film in said multilayer structure is formed as an uppermost layer.

12. A method for forming an insulating film for a semiconductor element, wherein a target and a substrate are disposed in a chamber, and, by changing the pressure of gas inside said chamber to a predetermined value, an insulating film is formed on said substrate by laser ablation of said target in said gas.

13. A method for forming an insulating film for a semiconductor element comprising:
a disposition step of disposing a target and a substrate in a chamber at a predetermined distance from each other;
an introducing step of introducing a prescribed gas inside said chamber;
a pressure transition step of causing a continuous transition of the pressure of gas inside said chamber, which has been introduced with said gas in said introducing step; and
a film forming step of forming an insulating film on said substrate by irradiating a laser beam toward said target from outside of the chamber having said gas introduced therein by a laser ablation method in the course of continuous transition of the pressure inside said chamber in said pressure transition step.

14. A method for forming an insulating film for a semiconductor element according to claim 12 or 13, wherein said insulating film is the insulating film for a semiconductor element according to any of claims 5 to 11.

15. A method for forming a porous film by which a porous film composed of silicon and oxygen and containing pres is formed on a substrate by a laser ablation method employing silicon as a target in a gas containing at least oxidant component.

16. A process according to claim 15, wherein the oxidant component contains at least one gas selected from the group consisting of O₂, N₂O, and O₃.

17. A method for forming a porous film comprising:
a disposition step of disposing a target comprising silicon and a substrate in a chamber at a predetermined distance from each other;
an introducing step of introducing a gas containing at least one oxidant component inside said chamber; and
a film forming step of forming a porous film composed of silicon and oxygen and containing pores on said substrate by irradiating a laser beam toward said target from outside of the chamber having said gas containing at least one oxidant component introduced therein, by a laser ablation method.

18. The method forming a porous film according to claim 17, wherein said film forming step comprises a step of adjusting the relative dielectric constant of said porous film so as to obtain a desired value.
